(19) United States
(12) Patent Application Publication
(10) Pub. No.: US 2020/0048760 A1
(43) Pub. Date: Feb. 13, 2020

(54) HIGH POWER IMPULSE MAGNETRON SPUTTERING PHYSICAL VAPOR DEPOSITION OF TUNGSTEN FILMS HAVING IMPROVED BOTTOM COVERAGE

(71) Applicant: APPLIED MATERIALS, INC., Santa Clara, CA (US)

(72) Inventors: KISHOR KALATHIPARAMBIL, SAN JOSE, CA (US); ADOLPH M ALLEN, OAKLAND, CA (US); JIANXIN LEI, FREMONT, CA (US); JOTHILINGAM RAMALINGAM, SUNNYVALE, CA (US); VIACHSLAV BABAYAN, SUNNYVALE, CA (US)

(21) Appl. No.: 16/534,246

(22) Filed: Aug. 7, 2019

Related U.S. Application Data
(60) Provisional application No. 62/717,990, filed on Aug. 13, 2018.

(51) Int. Cl. C23C 14/35; C23C 14/16

(52) U.S. Cl. CPC C23C 14/354; C23C 14/165

(57) ABSTRACT

Methods of forming a film layer using a HiPIMS PVD process include providing a bias to a substrate in a processing region of a process chamber, the substrate comprising a surface feature and the processing region of the process chamber comprising a sputter target, delivering at least one energy pulse to the sputter target to create a sputtering plasma of a sputter gas in the processing region, the at least one energy pulse having an average voltage between about 600 volts and about 1500 volts and an average current between about 50 amps and about 1000 amps at a frequency which is less than 5 kHz and greater than 100 Hz, and directing the sputtering plasma toward the sputter target to form an ionized species comprising material sputtered from the sputter target, the ionized species forming a film in the feature of the substrate having improved bottom coverage.

### CROSS-REFERENCE TO RELATED APPLICATIONS

This application claims priority to and the benefit of U.S. Provisional Patent Application Ser. No. 62/717,990, filed Aug. 13, 2018 which is incorporated herein by this reference in its entirety.

### FIELD

Embodiments of the present principles generally relate to the physical vapor deposition (PVD) of metallic films and more specifically to the high power impulse magnetron sputtering (HIPIMS) physical vapor deposition (PVD) of Tungsten films to improve bottom coverage of substrate features.

### BACKGROUND

Integrated circuits are made possible by processes that produce intricately patterned material layers on substrate surfaces. Producing patterned material on a substrate requires controlled methods for deposition of desired materials. Selectively depositing a film on a surface of a substrate is useful for patterning and other applications.

Substrate features, including contacts, vias, lines, and other features used to form interconnects, such as multilevel interconnects, which use metallic materials such as cobalt, tungsten, or copper for example, continue to decrease in size as manufacturers strive to increase circuit density and quality. Physical vapor deposition (PVD) process and methods of depositing films, such as Tungsten films, is widely used in the semiconductor industry but conventional PVD conditions show poor bottom coverage of substrate features, which are decreasing in size.

There is a continuing need to improve film layering in desired locations of substrate features, including bottom coverage.

### SUMMARY

Embodiments of methods for high power impulse magnetron sputtering (HIPIMS) physical vapor deposition (PVD) of metallic films, such as Tungsten films, to improve bottom coverage of substrate features, including high aspect ratio apertures in substrates are disclosed herein.

In some embodiments, a method of forming a film layer using a high power impulse magnetron sputtering physical vapor deposition process includes providing a bias to a substrate in a processing region of a process chamber, the substrate comprising at least one aperture in a surface of the substrate and the processing region of the process chamber having a sputter target, delivering at least one energy pulse to the sputter target to create a sputtering plasma of a sputter gas in the processing region of the process chamber, the at least one energy pulse having an average voltage between about 600 volts and about 1500 volts and an average current between about 50 amps and about 1000 amps at a frequency which is less than 5 kHz and greater than 100 Hz, and directing the sputtering plasma toward the sputter target to form an ionized species comprising material sputtered from the sputter target, the ionized species forming a film in at least the at least one aperture of the substrate.

In some other embodiments a method of forming a film layer using a high power impulse magnetron sputtering physical vapor deposition process includes providing a bias to a substrate in a processing region of a process chamber, the substrate comprising at least one aperture in a surface of the substrate and the processing region of the process chamber having a Tungsten-containing sputter target, delivering at least one energy pulse to the sputter target in the processing region of a process chamber to create a sputtering plasma of a sputter gas in the processing region of the process chamber, the at least one energy pulse having an average voltage between about 600 volts and about 1500 volts and an average current between about 50 amps and about 1000 amps at a frequency which is less than 5 kHz and greater than 100 Hz, and forming an ionized species comprising a Tungsten material sputtered from the Tungsten-containing sputter target, wherein the ionized species forms a Tungsten-containing layer in at least the at least one aperture of the substrate.

Other and further embodiments of the present principles are described below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the present principles and are therefore not to be considered limiting of scope, for the present principles may admit to other equally effective embodiments.

FIG. 1 depicts a high level block diagram of a physical vapor deposition (PVD) process chamber in which embodiments of the present principles can be applied in accordance with an embodiment of the present principles.

FIG. 2 depicts a partial cross-sectional view of a substrate including a substrate feature.

FIG. 3 depicts a TEM image of a Tungsten film layer deposited on a substrate as a result of an extremely low resistance (XLR) PVD process being performed on the substrate.

FIG. 4 depicts a TEM image of a Tungsten film layer deposited on a substrate as a result of a Cirrus PVD process being performed on the substrate.

FIG. 5 depicts a TEM image of a Tungsten film layer deposited on a substrate as a result of a HiPIMS PVD process being performed on the substrate in accordance with an embodiment of the present principles.

FIG. 6 depicts a flow diagram of a method of forming a film layer having improved bottom coverage for substrate features using a high power impulse magnetron sputtering physical vapor deposition process in accordance with an embodiment of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present principles provide methods to deposit metallic films, such as Tungsten films, on silicon-containing surfaces. Tungsten silicide is used as silicide formation layer in substrate features, such as high aspect ratio apertures, for contact application. Embodiments of the present principles advantageously improve bottom coverage of metallic films in substrate features, such as narrow trenches, using high power impulse magnetron sputtering physical vapor deposition.

In the following detailed description, numerous specific details are set forth in order to provide a thorough understanding of exemplary embodiments or other examples described herein. However, these embodiments and examples may be practiced without the specific details. In other instances, well-known methods, procedures, components, and/or circuits have not been described in detail, so as not to obscure the following description. Further, the embodiments disclosed are for exemplary purposes only and other embodiments may be employed in lieu of, or in combination with, the embodiments disclosed.

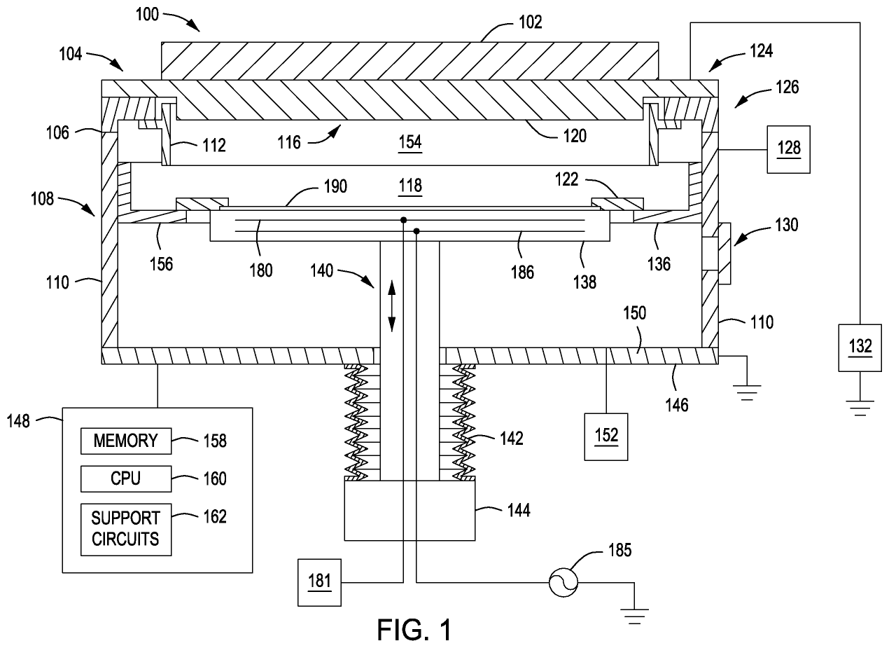

FIG. 1 illustrates an exemplary physical vapor deposition (PVD) process chamber 100 (e.g., a sputter process chamber) suitable for sputter depositing materials using a high power impulse magnetron sputtering (HiPIMS) process in accordance with an embodiment of the present principles. One example of the process chamber that may be adapted to form the Tungsten films in accordance with the present principles is a PVD process chamber, available from Applied Materials, Inc., located in Santa Clara, Calif. Other sputter process chambers, including those from other manufactures, may be adapted to practice the present principles.

The process chamber 100 includes a chamber body 108 having a processing volume 118 defined therein. The chamber body 108 has sidewalls 110 and a bottom 146. The dimensions of the chamber body 108 and related components of the process chamber 100 are not limited and generally are proportionally larger than the size of the substrate 190 to be processed. Any suitable substrate size may be processed. Examples of suitable substrate sizes include substrate with 200 mm diameter, 300 mm diameter, 450 mm diameter or larger.

A chamber lid assembly 104 is mounted on the top of the chamber body 108. The chamber body 108 may be fabricated from aluminum or other suitable materials. A substrate access port 130 is formed through the sidewall 110 of the chamber body 108, facilitating the transfer of a substrate 190 into and out of the process chamber 100. The access port 130 may be coupled to a transfer chamber and/or other chambers of a substrate processing system.

A gas source 128 is coupled to the chamber body 108 to supply process gases into the processing volume 118. In one embodiment, process gases may include inert gases, non-reactive gases, and reactive gases if necessary. Examples of process gases that may be provided by the gas source 128 include, but not limited to, argon gas (Ar), helium (He), neon gas (Ne), krypton (Kr), xenon (Xe), nitrogen gas (N.sub.2), oxygen gas (O.sub.2), hydrogen gas (H.sub.2), forming gas (N.sub.2+H.sub.2), ammonia (NH.sub.3), methane (CH.sub.4), carbon monoxide (CO), and/or carbon dioxide (CO.sub.2), among others.

A pumping port 150 is formed through the bottom 146 of the chamber body 108. A pumping device 152 is coupled to the processing volume 118 to evacuate and control the pressure therein. A pumping system and chamber cooling design enables high base vacuum (e.g., 1 E-8 Torr or less) and low rate-of-rise (e.g., 1,000 mTorr/min) at temperatures (e.g., −25 degrees Celsius to +650 degrees Celsius) suited to thermal budget needs. The pumping system is designed to provide precise control of process pressure which is a critical parameter for crystal structure (e.g., Sp3 content), stress control and tuning. Process pressure may be maintained in the range of between about 1 mTorr and about 500 mTorr, such as between about 2 mTorr and about 20 mTorr.

The lid assembly 104 generally includes a target 120 and a ground shield assembly 126 coupled thereto. The target 120 provides a material source that can be sputtered and deposited onto the surface of the substrate 190 during a PVD process. Target 120 serves as the cathode of the plasma circuit during, for example, DC sputtering.

The target 120 or target plate may be fabricated from a material utilized for the deposition layer, or elements of the deposition layer to be formed in the chamber, such as metallic materials. A high voltage power supply, such as a power source 132, is connected to the target 120 to facilitate sputtering materials from the target 120. In one embodiment, the target 120 may be fabricated from a metallic material, such as Tungsten, or the like. In other embodiments in accordance with the present principles, the target can comprise at least one of or a combination of Aluminum, Tin, Titanium, Tantalum and the like. The power source 132, or power supply, can provide power to the target in a pulsed (as opposed to constant) manner. That is, the power supply can provide power to the target by providing a number of pulses to the target 120.

The target 120 generally includes a peripheral portion 124 and a central portion 116. The peripheral portion 124 is disposed over the sidewalls 110 of the chamber. The central portion 116 of the target 120 may have a curvature surface slightly extending towards the surface of the substrate 190 disposed on a substrate support 138. In typical PVD processing, the spacing between the target 120 and the substrate support 138 is maintained between about 50 mm and about 250 mm. The dimension, shape, materials, configuration, and diameter of the target 120 may be varied for specific process or substrate requirements. In one embodiment, the target 120 may further include a backing plate having a central portion bonded and/or fabricated by a material desired to be sputtered onto the substrate surface.

The lid assembly 104 may further comprise a full face erosion magnetron cathode 102 mounted above the target 120 which enhances efficient sputtering materials from the target 120 during processing. The full face erosion magnetron cathode 102 allows easy and fast process control and tailored film properties while ensuring consistent target erosion and uniform deposition across the wafer. Examples of a magnetron assembly include a linear magnetron, a serpentine magnetron, a spiral magnetron, a double-digitated magnetron, a rectangularized spiral magnetron, among others shapes to form a desired erosion pattern on the target face and enable a desirable sheath formation during pulsed or DC plasma stages of the process. In some configurations, the magnetron may include permanent magnets that are positioned in a desirable pattern over a surface of the target, such as one of the patterns described above (e.g., linear, serpentine, spiral, double digitated, etc.). In other configurations, a variable magnetic field type magnetron having a desirable pattern may alternately, or even in addition to permanent magnets, be used to adjust the shape and/or density of the plasma throughout one or more portions of a HIPMS process.

The ground shield assembly 126 of the lid assembly 104 includes a ground frame 106 and a ground shield 112. The ground shield assembly 126 may also include other chamber shield member, target shield member, dark space shield, and dark space shield frame. The ground shield 112 is coupled to the peripheral portion 124 by the ground frame 106 defining an upper processing region 154 below the central portion of the target 120 in the processing volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source material to be mainly deposited on the substrate surface rather than chamber sidewalls 110.

In the embodiment of FIG. 1, a shaft 140 extending through the bottom 146 of the chamber body 108 couples to a lift mechanism 144. The lift mechanism 144 is configured to move the substrate support 138 between a lower transfer position and an upper processing position. A bellows 142 circumscribes the shaft 140 and coupled to the substrate support 138 to provide a flexible seal there between, thereby maintaining vacuum integrity of the chamber processing volume 118.

The substrate support 138 may be an electro-static chuck and have an electrode 180. The substrate support 138, when using the electro-static chuck (ESC) embodiment, uses the attraction of opposite charges to hold both insulating and conducting type substrates 190 and is powered by DC power supply 181. The substrate support 138 can include an electrode embedded within a dielectric body. The DC power supply 181 may provide a DC chucking voltage of about 200 to about 2000 volts to the electrode. The DC power supply 181 may also include a system controller for controlling the operation of the electrode 180 by directing a DC current to the electrode for chucking and de-chucking the substrate 190.

After the process gas is introduced into the process chamber 100, the gas is energized to form plasma so that the HIPIMS type PVD process can be performed.

A shadow frame 122 is disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing, an outer edge of the substrate 190 disposed on the substrate support 138 is engaged by the shadow frame 122 and the shadow frame 122 is lifted up and spaced away from the chamber shield 136. When the substrate support 138 is lowered to the transfer position adjacent to the substrate transfer access port 130, the shadow frame 122 is set back on the chamber shield 136. Lift pins (not shown) are selectively moved through the substrate support 138 to list the substrate 190 above the substrate support 138 to facilitate access to the substrate 190 by a transfer robot or other suitable transfer mechanism.

A controller 148 is coupled to the process chamber 100. The controller 148 includes a central processing unit (CPU) 160, a memory 158, and support circuits 162. The controller 148 is utilized to control the process sequence, regulating the gas flows from the gas source 128 into the process chamber 100 and controlling ion bombardment of the target 120. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100, such that the processes are performed in accordance with the present principles. The software routines may also be stored and/or executed by a second controller (not shown) that is located remotely from the process chamber 100.

During processing, material is sputtered from the target 120 and deposited on the surface of the substrate 190. In some configurations, the target 120 is biased relative to ground or substrate support, by the power source 132 to generate and maintain a plasma formed from the process gases supplied by the gas source 128. The ions generated in the plasma are accelerated toward and strike the target 120, causing target material to be dislodged from the target 120. The dislodged target material forms a layer on the substrate 190 with a desired crystal structure and/or composition. RF, DC or fast switching pulsed DC power supplies or combinations thereof provide tunable target bias for precise control of sputtering composition and deposition rates for the target material.

In some embodiments, separately applying a bias to the substrate during different phases of the film layer deposition process is also desirable. Therefore, a bias may be provided to a bias electrode 186 (or chuck electrode 180) in the substrate support 138 from a source 185 (e.g., DC and/or RF source), so that the substrate 190 will be bombarded with ions formed in the plasma during one or more phases of the deposition process. In some process examples, the bias is applied to the substrate after the film deposition process has been performed. Alternately, in some process examples, the bias is applied during the film deposition process. A larger negative substrate bias will tend to drive the positive ions generated in the plasma towards the substrate or vice versa, so that they have a larger amount of energy when they strike the substrate surface.

Referring back to the embodiment of FIG. 1, the power source 132 of the embodiment of FIG. 1 is a HIPIMS power supply configured to deliver power impulses to the target 120 with high current and high voltage over short durations within a range of frequencies. The inventors determined that performing a high power impulse magnetron sputtering PVD process in which high current and high voltage pulses within a specific range of low pulse frequencies are provided to a target, such as a Tungsten target, along with providing a substrate bias to the substrate 190 being processed improves a bottom coverage of deposited films in features of the substrate.

That is, when the high current and high voltage pulses in the ranges of between about from 50 amps-1000 amps and 600 volts-1500 volts the HIPIMS power supply 132 are delivered to the target 120 at a range of low frequencies of between about 100 Hz-5 kHz, a higher ion/neutrals ratio of sputtered target material is generated. The high voltage, high current pulses at the low frequencies generate high peak power which assists in ionizing the sputtered atoms. The resulting high ion fraction pulse to the substrate, combined with a substrate bias of between about 20 W and 300 W at 13.56 Mhz, enhances the material flux into the features (vias/trenches) of the substrate 190, increasing the bottom coverage of a resulting film layer.

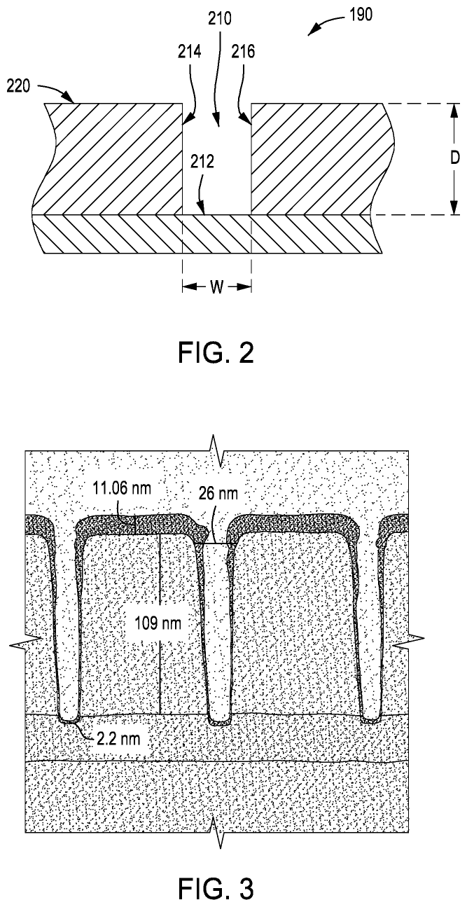

FIG. 2 depicts a partial cross-sectional view of a substrate 190 including a substrate feature 210. The shape or profile of the feature 210 can be any suitable shape or profile including, but not limited to, (a) vertical sidewalls and bottom surface, (b) tapered sidewalls, (c) under-cutting, (d) reentrant profile, (e) bowing, (f) micro-trenching, (g) curved bottom surface, and (h) notching. As used in this regard, the term “feature” means any intentional surface irregularity. Suitable examples of features include, but are not limited to trenches and holes, which can include a top, two sidewalls and a bottom, and peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

For example, in the illustrative embodiment of FIG. 2, the feature 210 extends from a surface 220 of the substrate 190 to a depth D, to the bottom surface 212. The feature 210 has a first sidewall 214 and a second sidewall 216 that define a width W of the feature 210. The open area formed by the sidewalls and bottom are also referred to as a gap. Although in the embodiment of FIG. 2, the substrate 190 is depicted as having a single feature, those skilled in the art will understand that a substrate can include more than one feature in accordance with the present principles.

In accordance with embodiments of the present principles, performing a HiPIMS PVD process on a substrate using a metallic target, such as Tungsten, at low frequencies and including a substrate bias improves the bottom coverage of a resulting deposited film layer, such as a Tungsten layer, in features of the substrate being processed. For example, FIGS. 3-5 depict respective TEM images of a Tungsten film deposited in high aspect ratio features of a substrate after three different PVD processes are performed on the substrate. Three different PVD processes having varying target powers, biases and pressures were selected to clearly demonstrate the improved bottom coverage of a PVD process in accordance with the present principles. More specifically, FIG. 3 depicts a TEM image of a Tungsten film layer deposited on a substrate as a result of an extremely low resistance (XLR) PVD process being performed on the substrate. The substrate of FIG. 3 illustratively includes three features. As depicted in FIG. 3, the bottom coverage of the deposited Tungsten film layer in the features of the substrate is approximately 20%. That is, as depicted in FIG. 3, a film layer resulting from the application of the XLR PVD process on a surface of the substrate measures approximately 11.06 nm. A film layer resulting in a bottom surface of the feature depicted in FIG. 3 having a width of approximately 26 nm and a depth of 109 nm measures 2.2 nm. As such, the bottom coverage of the deposited Tungsten film layer in the features of the substrate depicted in FIG. 3 is approximately 20 %. For the XLR PVD process of FIG. 3, the target bias (Power) was DC 900 W, the substrate bias was 300 W and the chamber pressure was set to 5.5 mTorr.

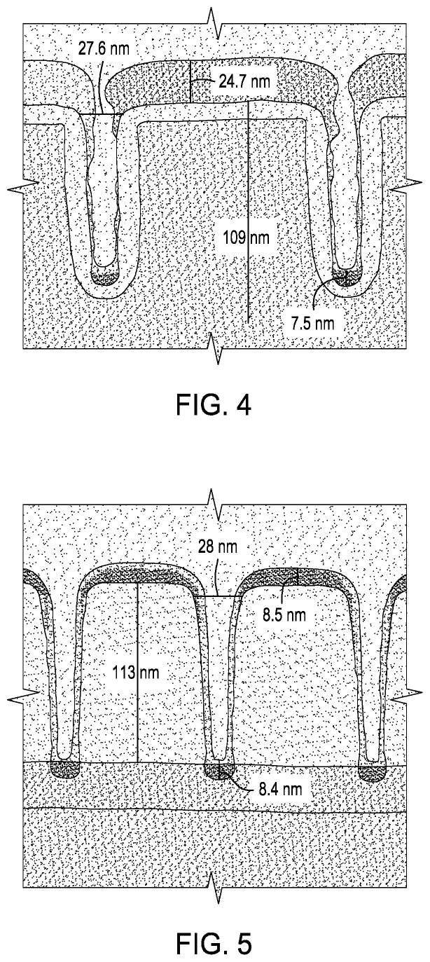

FIG. 4 depicts a TEM image of a Tungsten film layer deposited on a substrate as a result of a Cirrus PVD process being performed on the substrate. The substrate of FIG. 4 illustratively includes two features. As depicted in FIG. 4, the bottom coverage of the deposited Tungsten film layer in the features of the substrate is approximately 30%. That is, as depicted in FIG. 4, a film layer resulting from the application of the Cirrus PVD process on a surface of the substrate measures approximately 24.7 nm. A film layer resulting in a bottom surface of the feature depicted in FIG. 4 having a width of approximately 27.6 nm and a depth of 109 nm measures 7.5 nm. As such, the bottom coverage of the deposited Tungsten film layer in the features of the substrate depicted in FIG. 4 is approximately 30%. For the Cirrus PVD process of FIG. 4, the target bias (Power) was DC 500 W, the substrate bias was 4.5 kW and the chamber pressure was set to 90 mTorr.

FIG. 5 depicts a TEM image of a Tungsten film layer deposited on a substrate as a result of a HiPIMS PVD process being performed on the substrate in, for example, the PVD process chamber 100 of FIG. 1, in accordance with an embodiment of the present principles. The substrate of FIG. 5 illustratively includes three features, illustratively three high aspect ratio apertures. In the embodiment of FIG. 5, the HiPIMS pulse was delivered with a target bias of 1010V having a peak current of 127 A at a frequency of 2 kHz and the substrate bias was set to 100 W. As depicted in FIG. 5, the depth of a resulting Tungsten film layer deposited on a surface of the substrate measured 8.5 nm and the depth of the resulting Tungsten film layer deposited at the bottom of a feature of the substrate having a width of 28 nm and a depth of 113 nm measured 8.4 nm. As such, by performing a HiPIMS PVD process on a substrate using a Tungsten target having a target bias of 1010V, a peak current of 127 A, at a frequency of 2 kHz with a substrate bias set to 100 W, in accordance with an embodiment of the present principles, the bottom coverage of the deposited Tungsten film layer in the features of the substrate was approximately 98%.

As illustrated by FIGS. 3-5 above, by providing an HV Pulsed DC signal with high voltage and high current at lower frequencies than typically provided in conventional HiPIMS PVD processes and providing a suitable substrate bias for a substrate being processed in accordance with the present principles, higher ion/neutrals ratio of sputtered target material is generated which enhances the material flux into the features (vias/trenches) of the substrate 190, increasing the bottom coverage of a resulting film layer.

The inventors further determined that by using a HiPIMS PVD process to process a substrate having features in accordance with the embodiments of the present principles described above, a lower pressure can be used in the PVD process chamber 100 during processing. For example, in the example of FIG. 5 above, the PVD process chamber pressure was set to 0.97 mTorr during the HiPIMS PVD process which yielded a Tungsten film layer having a bottom coverage of over 90% for the features of the substrate.

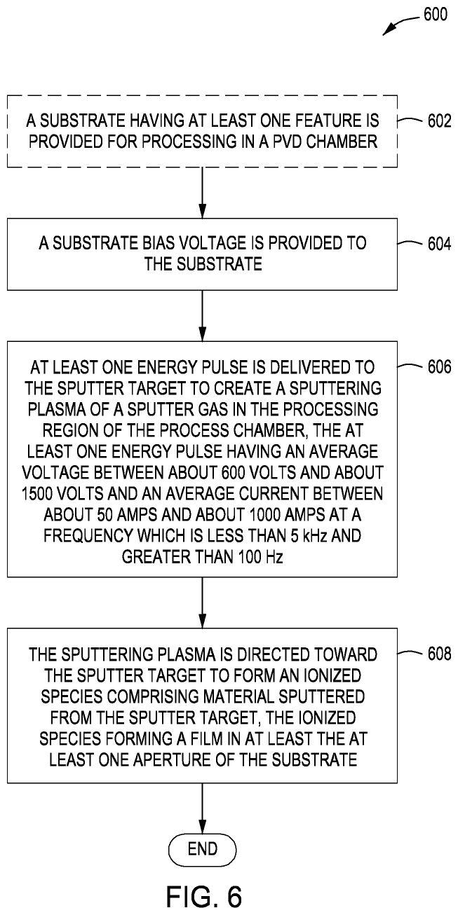

FIG. 6 depicts a flow diagram of a method 600 of forming a film layer having improved bottom coverage for substrate features using a high power impulse magnetron sputtering physical vapor deposition process in accordance with an embodiment of the present principles. The method 600 begins at optional step 602 during which a substrate 190 including at least one feature is provided for processing in the PVD process chamber 100. As used in this regard, the term “provided” means that the substrate is placed into a position or environment for PVD processing. In alternate embodiments in accordance with the present principles, the method begins when a substrate including at least one feature is already present in a process chamber. The method 600 can then proceed to 604.

At 604, a substrate bias of between about 20 W and 300 W is provided to the substrate 190. The method 600 can then proceed to 606.

At 606, at least one energy pulse, and typically a series of energy pulses, are delivered to a target in the PVD process chamber. In general, the energy pulses provided during 604 include the selection of at least a target bias voltage, pulse width and pulse frequency that form a plasma that will impart a desirable amount of energy to achieve a desirable plasma energy and plasma density to achieve a high ion/neutrals ratio of the sputtered atoms to achieve improved bottom coverage of deposited film layers for features of the substrate. In one embodiment and as described above, the energy pulses used to form the sputtering plasma can each have an average voltage between about 600 volts and about 1500 volts and an average current between about 50 amps and about 1000 amps at a frequency which is less than 5 kHz and greater than 100 Hz. The high voltage, high current pulses provided to the target at frequencies which are lower than typical HiPIMS PVD processes, generate high peak power which assists in ionizing the sputtered atoms. The method 600 can then proceed to 608.

At 608, once the plasma is formed, an ionized species of the sputter gas (sputtering plasma) is accelerated (directed) towards the target and collides with the target. These collisions remove target atoms forming an ionized species comprising target material sputtered from the target. The target atoms deposit on the surface of the substrate and form a film on the substrate. The resulting high ion fraction target atoms, combined with the substrate bias, enhances the material flux into the features (vias/trenches) of the substrate 190, increasing the bottom coverage of a resulting film layer in the features of the substrate 190. The method 600 can then be exited.

The high energy pulse power, the lower than normal PVD frequency and the substrate bias during a PVD process, as described above and in accordance with the present principles, result in a film layer, such as a Tungsten film layer, having increased bottom coverage for substrate features.

While the foregoing is directed to embodiments of the present principles, other and further embodiments may be devised without departing from the basic scope thereof.

1. A method of forming a film layer using a high power impulse magnetron sputtering physical vapor deposition process, comprising:
providing a bias to a substrate in a processing region of a process chamber, the substrate comprising at least one aperture in a surface of the substrate and the processing region of the process chamber having a sputter target;
delivering at least one energy pulse to the sputter target to create a sputtering plasma of a sputter gas in the processing region of the process chamber, the at least one energy pulse having an average voltage between about 600 volts and about 1500 volts and an average current between about 50 amps and about 1000 amps at a frequency which is less than 5 kHz and greater than 100 Hz; and
directing the sputtering plasma toward the sputter target to form an ionized species comprising material sputtered from the sputter target, the ionized species forming a film in at least the at least one aperture of the substrate.

2. The method of claim 1, wherein the film comprises a Tungsten film.

3. The method of claim 2, wherein the energy pulse is delivered at a frequency of 2 kHz.

4. The method of claim 1, wherein the process chamber during processing is maintained at a pressure of about 1 mTorr.

5. The method of claim 1, wherein the sputter target is a Tungsten target.

6. The method of claim 1, wherein the sputter gas comprises a gas which is inert to at least one of the substrate or the sputter target.

7. The method of claim 6, wherein the sputter gas comprises argon.

8. The method of claim 1, wherein the substrate bias is between about 20 watts and 300 watts.

9. The method of claim 1, wherein the substrate bias is 100 watts.

10. The method of claim 1, wherein the substrate bias is provided at a frequency of 13.56 Mhz.

11. The method of claim 1, wherein the sputter target is made of at least one of Aluminum, Tin, Titanium or Tantalum and the film comprises at least one of Aluminum, Tin, Titanium or Tantalum.

12. The method of claim 1, wherein a ratio of the film formed in the at least one aperture of the substrate to a film formed on the surface of the substrate is greater than 90 percent.

13. A method of forming a Tungsten film layer using a high power impulse magnetron sputtering physical vapor deposition process, comprising:
providing a bias to a substrate in a processing region of a process chamber, the substrate comprising at least one aperture in a surface of the substrate and the processing region of the process chamber having a Tungsten-containing sputter target;
delivering at least one energy pulse to the sputter target in the processing region of a process chamber to create a sputtering plasma of a sputter gas in the processing region of the process chamber, the at least one energy pulse having an average voltage between about 600 volts and about 1500 volts and an average current between about 50 amps and about 1000 amps at a frequency which is less than 5 kHz and greater than 100 Hz; and
forming an ionized species comprising a Tungsten material sputtered from the Tungsten-containing sputter target, wherein the ionized species forms a Tungsten-containing layer in at least the at least one aperture of the substrate.

14. The method of claim 13, wherein the energy pulse is delivered at a frequency of 2 kHz.

15. The method of claim 13, wherein the process chamber during processing is maintained at a pressure of less than 1 mTorr.

16. The method of claim 13, wherein the substrate bias is 100 watts.

17. The method of claim 13, wherein the sputter gas comprises argon.

18. The method of claim 13, wherein the substrate bias is provided at a frequency of 13.56 Mhz.

19. The method of claim 13, wherein a ratio of the film formed in the at least one aperture of the substrate to a film formed on the surface of the substrate is greater than 90 percent.

20. The method of claim 13, wherein the at least one energy pulse comprises an average voltage of 1010 volts and an average current of 127 amps.
